(19) United States
(12) Patent Application Publication
(10) Pub. No.: US 2025/0357162 A1
(43) Pub. Date: Nov. 20, 2025

(54) SUBSTRATE TRANSPORT CHAMBER WITH IN-SITU NITROGEN PURGE FUNCTION AND APPARATUS USING THE SAME

(71) Applicant: ASM IP Holding B.V., Almere (NL)

(72) Inventor: Christopher Cillie, Scottsdale, AZ (US)

(21) Appl. No.: 19/205,487

(22) Filed: May 12, 2025

Related U.S. Application Data
(60) Provisional application No. 63/647,284, filed on May 14, 2024.

(51) Int. Cl. H01L 21/67

(52) U.S. Cl. CPC H01L 21/67196

(57) ABSTRACT

Provided is a substrate transport chamber including a substrate transport chamber and an air separation unit. The air separation unit separates an air into a nitrogen and an oxygen. The nitrogen separated from the air is supplied to the substrate transport unit to purge the substrate transport unit and the oxygen separated from the air is exhausted outside of the substrate transport chamber.

### CROSS-REFERENCE TO RELATED APPLICATION(S)

This Application claims the benefit of U.S. Provisional Application 63/647,284 filed on May 14, 2024, the entire contents of which are incorporated herein by reference.

### FIELD OF INVENTION

The disclosure relates to a substrate transport chamber, more particularly to a substrate transport chamber with a nitrogen in-situ purge function and an apparatus using the same.

### BACKGROUND OF THE DISCLOSURE

A substrate processing cluster tool to process a semiconductor substrate comprises a substrate transport chamber, a load-lock chamber, a substrate handling chamber and a substrate processing chamber.

FIG. 1 illustrates a conventional substrate processing cluster tool 100. As shown in FIG. 1, one side of the substrate handling chamber 150 may be connected to the load-lock chamber 140 and the other side of the substrate handling chamber 150 may be connected to the substrate process chamber 160. The load-lock chamber 140 may be connected to the substrate transport chamber 130.

The substrate transport chamber 130 may be an equipment front end module (EFEM). The substrate transport chamber 130 may comprise a substrate transport unit 110 and an air supply unit 120. The substrate transport chamber 130, the load-lock chamber 140, the substrate handling chamber 150 and the substrate process chamber 160 may be isolated each other by isolation valves 170. The isolation valve 170 may be open when the substrate travels to other chambers or closed otherwise.

A substrate 200 to be processed may travel from the substrate transport unit 110 to the load-lock chamber 140 by a front-end robot arm 180, from the load-lock chamber 140 to the substrate process chamber160 via the substrate handling chamber 150 by a back-end robot arm 190. After the substrate 200 may be processed in the substrate process chamber 160, the substrate 200 may travel back to the substrate transport unit 110 via the substrate handling chamber 150 and the load lock chamber 140.

The substrate transport unit 110 may be supplied with an air from an air supply unit 120 to flow an air from the top to the bottom of the substrate transport unit 110. The air flow in the substrate transport unit 110 may prevent contaminants such as particles from dropping and stacking up on the substrate. The air, however, may contain an oxygen and causes a film formed on the substrate to be oxidized, resulting in deterioration of the film properties.

### SUMMARY OF THE DISCLOSURE

The disclosure relates to a substrate transport chamber, more particularly to a substrate transport chamber with an in-situ nitrogen purge function and an apparatus using the same to prevent the oxidation of a substrate in a substrate transport chamber.

In one or more embodiments, a substrate transport chamber may comprise a substrate transport unit and an air separation unit in fluid communication with the substrate transport unit, wherein the air separation unit may comprise a filter unit.

In one or more embodiments, the air separation unit may further comprise an inlet unit, a first outlet unit and a second outlet unit, wherein one end of the inlet unit may be open to the air outside of the air separation unit.

In one or more embodiments, the inlet unit may further comprise a suction unit.

In one or more embodiments, one end of the first outlet unit may be open to an air outside of the air separation unit.

In one or more embodiments, the substrate transport chamber may further comprise a cover unit connected to the first outlet unit and spaced apart from the substrate transport unit.

In one or more embodiments, the cover unit may surround the substrate transport unit.

In one or more embodiments, the first outlet unit may further comprise a first exhaust unit.

In one or more embodiments, the air separation unit may be in fluid communication with the substrate transport unit through the second outlet unit.

In one or more embodiments, the substrate transport chamber may further comprise a second exhaust unit to exhaust the air separation unit.

In one or more embodiments, a method of purging a substrate transport chamber comprising a substrate transport unit and an air separation unit in fluid communication with the substrate transport unit may comprise supplying an air to the air separation unit from outside of the substrate transfer chamber, separating a nitrogen and an oxygen from the air in the air separation unit, supplying the nitrogen to the substrate transport unit to purge the substrate transport unit and exhausting the oxygen to outside of the substrate transport chamber.

In one or more embodiments, a method of purging the substrate transport chamber further comprising a cover unit spaced apart from the substrate transport unit may comprise exhausting the oxygen through a space between the cover unit and the substrate transport unit.

In one or more embodiments, a substrate processing cluster tool may comprise a substrate transport chamber, a load-lock chamber connected to the substrate transport chamber, a substrate handling chamber connected to the load-lock chamber, and a substrate process chamber connected to the substrate handling chamber, wherein the substrate transport chamber may comprise a substrate transport unit and an air separation unit in fluid communication with the substrate transport unit.

In one or more embodiments, the substrate transport chamber may further comprise a first substrate transfer unit to transfer a substrate from the substrate transport chamber to the load-lock chamber, and the substrate handling chamber may further comprise a second substrate transfer unit to transfer the substrate from the load-lock chamber to the substrate process chamber.

In one or more embodiments, the substrate processing cluster tool may further comprise isolation valves configured to isolate between the substrate transport chamber and the load-lock chamber, between the load-lock chamber and the substrate handling chamber, and between the substrate handling chamber and the substrate process chamber.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a conventional substrate processing cluster tool.

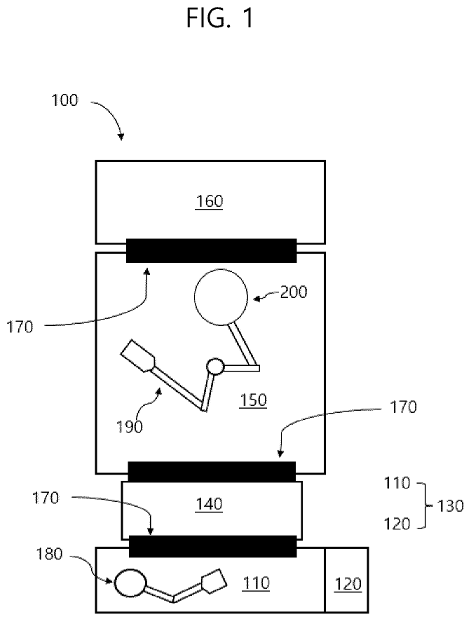

FIG. 2 illustrates an embodiment of a substrate transport chamber according to the disclosure.

FIG. 3 illustrates another embodiment of a substrate transport chamber according to the disclosure.

FIG. 4 illustrates a method of purging a substrate transport chamber according to an embodiment of the disclosure.

FIG. 5 illustrates a substrate processing cluster tool according to the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

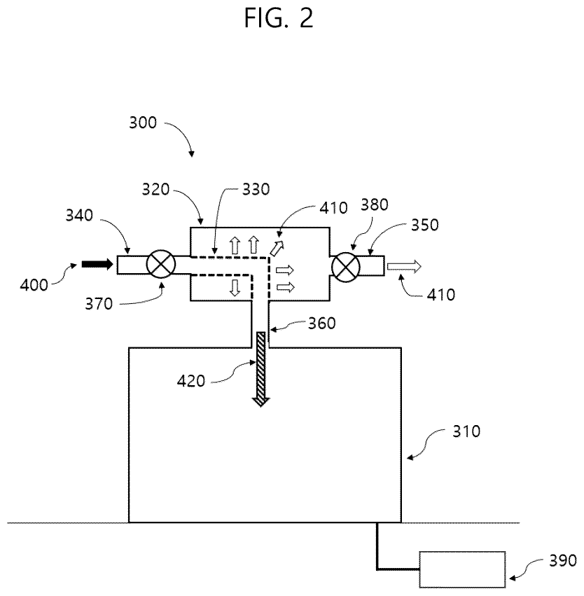

FIG. 2 illustrates an embodiment of a substrate transport chamber 300 according to the disclosure. The substrate transport chamber may be an equipment front end module (EFEM).

In FIG. 2, a substrate transport chamber 300 may comprise a substrate transport unit 310 and an air separation unit 320. The air separation unit 320 may further comprise an inlet unit 340, a first outlet unit 350 and a second outlet unit 360. The air separation unit 320 may comprise a filter unit 330 to separate an air 400 supplied to the air separation unit 320 by a molecular size.

For instance, the filter unit 330 may separate a nitrogen 420 and an oxygen 410 from the air 400. The filter unit 330 may be configured to allow the oxygen 410 smaller than the nitrogen 420 to pass through the filter unit 330. In contrast, the filter unit 330 may be configured not to allow the nitrogen 420 bigger than the oxygen 410 to pass through the filter unit 330.

Therefore, the oxygen 410 passing through the filter unit 330 may be exhausted to the air (e.g., fab environment) outside of the air separation unit 320 through the first outlet unit 350. In contrast, the nitrogen 420 may be supplied to the substrate transport unit 310, resulting in purging the substrate transport unit 310.

The nitrogen 420 may be pure nitrogen, or nitrogen-rich air. The oxygen 410 may be pure oxygen, or oxygen-rich air.

One end of the inlet unit 340 may be open to an air (e.g., fab environment) outside of the air separation unit 320. The inlet unit 340 may further comprise a suction unit 370 to facilitate to supply the air 400 to the air separation unit 320. In one embodiment, the suction unit 370 may be a fan.

One end of the first outlet unit 350 may be open to the air (e.g., fab environment) outside of the air separation unit 320. The first outlet unit 350 may further comprise a first exhaust unit 380 to facilitate to exhaust the oxygen 410 from the air separation unit 320. In one embodiment, the first exhaust unit 380 may be a fan.

The air separation unit 320 may be in fluid communication with the substrate transport unit 310 through the second outlet unit 360.

The substrate transport unit 310 may further comprise a second exhaust unit 390 to exhaust the substrate transport unit 310. In one embodiment, the second exhaust unit 390 may be a fan. Therefore, a laminar flow of the nitrogen 420 may be formed from the top to the bottom of the substrate transport unit 310.

The laminar flow of the nitrogen in the substrate transport unit 310 may suppress contaminants (e.g., particles) from drifting in the space and carry contaminants to the bottom of the substrate transport unit 310, resulting in preventing contaminants from stacking up on the substrate.

Since the substrate transport unit 310 may be purged with the nitrogen 420 as a purge gas in-situ, a substrate staying therein may be prevented from being oxidized.

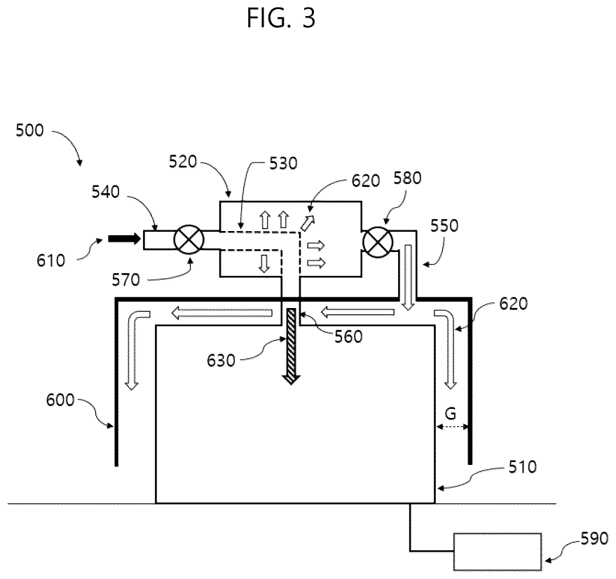

FIG. 3 illustrates another embodiment of a substrate transport chamber 500 according to the disclosure. The substrate transport chamber 500 may be an equipment front end module (EFEM).

In FIG. 3, a substrate transport chamber 500 may comprise a substrate transport unit 510 and an air separation unit 520. The air separation unit 520 may further comprise an inlet unit 540, a first outlet unit 550 and a second outlet unit 560.

The substrate transport chamber 500 may further comprise a cover unit 600. The cover unit 600 may be connected to the first outlet unit 550 and spaced apart from the substrate transport unit 510. The cover unit 600 may be configured to surround the substrate transport unit 510.

The air separation unit 520 may comprise a filter unit 530 to separate an air 610 supplied to the air separation unit 520 by a molecular size.

For instance, the filter unit 530 may separate a nitrogen 630 and an oxygen 620 from the air 610. The filter unit 530 may be configured to allow the oxygen 620 smaller than the nitrogen 630 to pass through the filter unit 530. In contrast, the filter unit 530 may be configured not to allow the nitrogen 630 bigger than the oxygen 620 to pass through the filter unit 530.

Therefore, the oxygen 620 passing through the filter unit 530 may be exhausted through a space G formed between the cover unit 600 and the substrate transport unit 510 through the first outlet unit 550. In contrast, the nitrogen 630 may be supplied to the substrate transport unit 510, resulting in purging the substrate transport unit 510.

The nitrogen 630 may be pure nitrogen, or nitrogen-rich air. The oxygen 620 may be pure oxygen, or oxygen-rich air.

One end of the inlet unit 540 may be open to an air (e.g., fab environment) outside of the air separation unit 520. The inlet unit 540 may further comprise a suction unit 570 to facilitate to supply the air 610 to the air separation unit 520. In one embodiment, the suction unit 570 may be a fan.

One end of the first outlet unit 550 may be connected to the cover unit 600. The first outlet unit 550 may further comprise a first exhaust unit 580 to facilitate to exhaust the oxygen 620 from the air separation unit 520. In one embodiment, the first exhaust unit 580 may be a fan.

The air separation unit 520 may be in fluid communication with the substrate transport unit 510 through the second outlet unit 560.

The substrate transport unit 510 may further comprise a second exhaust unit 590 to exhaust the substrate transport unit 510. In one embodiment, the second exhaust unit 590 may be a fan. Therefore, a laminar flow of the nitrogen 630 may be formed from the top to the bottom of the substrate transport unit 510.

The laminar flow of the nitrogen in the substrate transport unit 510 may suppress contaminants (e.g., particles) from drifting in the space and carry contaminants to the bottom of the substrate transport unit 510, resulting in preventing contaminants from stacking up on the substrate.

Since the substrate transport unit 510 may be purged with the nitrogen 630 as a purge gas in-situ, a substrate staying therein may be prevented from being oxidized.

In FIG. 3, the cover unit 600 may surround the substrate transport unit 510 and the oxygen 620 may be supplied in the space G between the cover unit 600 and the substrate transport unit 510, resulting in forming a gas (i.e., oxygen) curtain therebetween. Thus, an operator of the substrate transport chamber 500 may be protected from the leak of nitrogen from the substrate transport unit 510.

The substrate transport chamber according to the disclosure may allow to recycle an air in the fab environment to generate and supply a nitrogen to the substrate transport unit without separate facilities to generate and supply a nitrogen. Therefore, the disclosure may provide a cost-saving way of generating a nitrogen and purging the substrate transport chamber with the nitrogen as a purge gas in-situ.

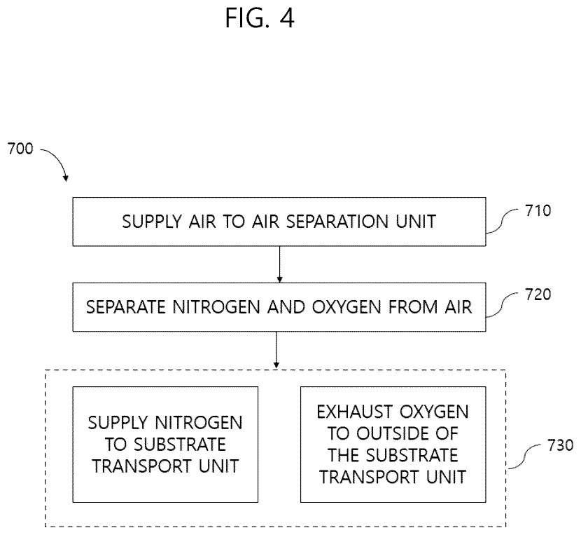

FIG. 4 illustrates a method of purging a substrate transport chamber according to an embodiment of the disclosure.

In FIG. 4, the method may be performed in a substrate transport chamber 500 comprising a substrate transport unit 510 and an air separation unit 520 as illustrated in FIG. 3.

In STEP 710, supplying an air to an air separation unit may be performed. For instance, as illustrated in FIG. 3, the air 610 may be supplied to the air separation unit 520 through the inlet unit 540.

In STEP 720, separating a nitrogen and an oxygen from the air in the air separation unit may be performed. For instance, as illustrated in FIG. 3, an oxygen 620 may pass through the filter unit 530 and an nitrogen may not pass through the filter unit 530. resulting in being supplied to the substrate transport unit 510.

In STEP 730, supplying the nitrogen to the substrate transport unit to purge the substrate transport unit and exhausting the oxygen to outside of the substrate transport chamber may be performed. For instance, as illustrated in FIG. 3, an oxygen 620 passing through the filter unit 530 may be exhausted to the space G outside of the substrate transport chamber 500 through the first outlet unit 550. In contrast, a nitrogen 630 may not pass through the filter unit 530, resulting in being supplied to the substrate transport unit 510.

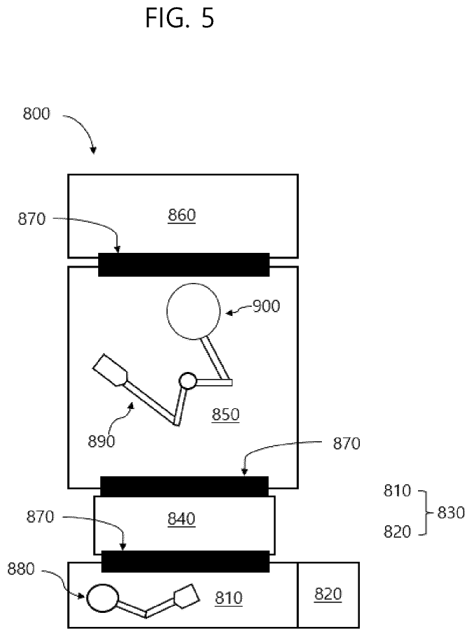

FIG. 5 illustrates a substrate processing cluster tool according to an embodiment of the disclosure.

In FIG. 5, the substrate processing cluster tool 800 may comprise a substrate transport chamber 830, a load-lock chamber 840 connected to the substrate transport chamber 830, a substrate handling chamber 850 connected to the substrate transport chamber 830, and a substrate process chamber 860 connected to the substrate handling chamber 850. The substrate transport chamber 830 may be an equipment front end module (EFEM). In the substrate process chamber 860, a substrate 900 may be processed (e.g., deposition, etching, cleaning and CMP etc.).

The substrate transport chamber 830 may comprise a substrate transport unit 810 and an air separation unit 820 in fluid communication with the substrate transport unit 810.

The substrate transport chamber 830 may further comprise a first substrate transfer unit 880 to transfer a substrate 900 from the substrate transport chamber 830 to the load-lock chamber 840. In one embodiment, the first substrate transfer unit may be a front-end robot arm.

The substrate handling chamber 850 may further comprise a second substrate transfer unit 890 to transfer the substrate 900 from the load-lock chamber 840 to the substrate process chamber 860. In one embodiment, the second substrate transfer unit 890 may be a back-end robot arm.

The substrate processing cluster tool 800 may further comprise isolation valves 870 configured to isolate between the substrate transport chamber 830 and the load-lock chamber 840, between the load-lock chamber 840 and the substrate handling chamber 850, and between the substrate handling chamber 850 and the substrate process chamber 860.

1. A substrate transport chamber comprising:
a substrate transport unit; and
an air separation unit in fluid communication with the substrate transport unit,
wherein the air separation unit comprises a filter unit.

2. The substrate transport chamber of claim 1, wherein the air separation unit further comprises an inlet unit, a first outlet unit and a second outlet unit,
wherein one end of the inlet unit is open to the air outside of the air separation unit.

3. The substrate transport chamber of claim 2, wherein the inlet unit further comprises a suction unit.

4. The substrate transport chamber of claim 3, wherein the suction unit comprises a fan.

5. The substrate transport chamber of claim 2, wherein one end of the first outlet unit is open to an air outside of the air separation unit.

6. The substrate transport chamber of claim 2, further comprising a cover unit connected to the first outlet unit and spaced apart from the substrate transport unit.

7. The substrate transport chamber of claim 6, wherein the cover unit surrounds the substrate transport unit.

8. The substrate transport chamber of claim 2, wherein the first outlet unit further comprises a first exhaust unit.

9. The substrate transport chamber of claim 8, wherein the first exhaust unit comprises a fan.

10. The substrate transport chamber of claim 2, wherein the air separation unit is in fluid communication with the substrate transport unit through the second outlet unit.

11. The substrate transport chamber of claim 1, further comprising a second exhaust unit to exhaust the air separation unit.

12. The substrate transport chamber of claim 11, the second exhaust unit is a fan.

13. A method of purging a substrate transport chamber comprising a substrate transport unit and an air separation unit in fluid communication with the substrate transport unit, comprising:
supplying an air to the air separation unit from outside of the substrate transfer chamber;
separating a nitrogen and an oxygen from the air in the air separation unit;
supplying the nitrogen to the substrate transport unit to purge the substrate transport unit; and
exhausting the oxygen to outside of the substrate transport chamber.

14. The method of purging a substrate transport chamber of claim 13, wherein the substrate transport chamber further comprises a cover unit spaced apart from the substrate transport unit, wherein the oxygen is exhausted through a space between the cover unit and the substrate transport unit.

15. A substrate processing cluster tool comprising:
a substrate transport chamber;
a load-lock chamber connected to the substrate transport chamber;
a substrate handling chamber connected to the load-lock chamber; and
a substrate process chamber connected to the substrate handling chamber,
wherein the substrate transport chamber comprises a substrate transport unit and an air separation unit in fluid communication with the substrate transport unit.

16. The substrate processing cluster tool of claim 15, wherein the substrate transport chamber further comprises a first substrate transfer unit to transfer a substrate from the substrate transport chamber to the load-lock chamber,
wherein the substrate handling chamber further comprises a second substrate transfer unit to transfer the substrate from the load-lock chamber to the substrate process chamber.

17. The substrate processing cluster tool of claim 15, further comprising isolation valves configured to isolate between the substrate transport chamber and the load-lock chamber, between the load-lock chamber and the substrate handling chamber, and between the substrate handling chamber and the substrate process chamber.
